(19) United States
(12) Patent Application Publication
(10) Pub. No.: US 2017/0054051 A1
(43) Pub. Date: Feb. 23, 2017

(54) ADDITIONAL TEMPERATURE TREATMENT STEP FOR THIN-FILM SOLAR CELLS

(71) Applicants: CHINA TRIUMPH INTERNATIONAL ENGINEERING CO., LTD., Shanghai (CN); CTF SOLAR GMBH, Dresden (DE)

(72) Inventors: Shou Peng, Shanghai (CN); Bettina Späth, Dresden (DE); Michael Harr, Dresden (DE); Sven Frauenstein, Dresden (DE)

(73) Assignees: CHINA TRIUMPH INTERNATIONAL ENGINEERING CO., LTD., Shanghai (CN); CTF SOLAR GMBH, Dresden (DE)

(21) Appl. No.: 15/307,330

(22) PCT Filed: Apr. 24, 2015
(86) PCT No.: PCT/CN2015/077347

§ 371 Date: Oct. 27, 2016

(30) Foreign Application Priority Data
Apr. 29, 2014 (DE) 1020142080290

(51) Int. Cl. H01L 31/18; H01L 31/073

(52) U.S. Cl. CPC H01L 31/1864; H01L 31/1828; H01L 31/186; H01L 31/073; H01L 31/1836

(57) ABSTRACT

The present invention refers to a method for producing CdTe thin-film solar cells, respectively a semi-finished CdTe thin-film solar cell, where in an additional temperature step is carried out after applying the CdTe layer on to a substrate. In particular, the temperature step is performed after activating the CdTe layer using a suitable activation agent and removing the residual activation agent from the CdTe layer. The temperature treatment is performed under vacuum or in a heating chamber filled with either air or inert gas, during which treatment the substrate is exposed to a temperature between 180° C. and 380° C. for a time between 5 minutes and 60 minutes. Due to the inventive additional temperature step, the number and extension of crystal defects in the CdTe layer is reduced and the electric efficiency of the solar cell is further improved.

### TECHNICAL FIELD

The present invention refers to an improved method for producing CdTe thin-film solar cells, respectively a semi-finished product for same, wherein the method provides for carrying out an additional temperature step after applying the CdTe layer.

### BACKGROUND

Thin-film solar cells can be produced using the superstrate method or the substrate method.

In the production of thin-film solar cells using the superstrate method according to the state of the art, on a substrate, usually of glass, a transparent front contact layer (e.g. TCO, i.e. transparent conducting oxide) is deposited. On this front contact layer, a window layer, preferably made of pure or modified CdS (cadmium sulfide) is deposited and subsequently, a layer of CdTe (cadmium telluride) is deposited on top of this. Finally the back contact layer is added.

In the state of the art, after depositing the CdTe layer, this layer needs to be activated. This is done by exposing the CdTe layer at a raised temperature (usually about 380° C. to 440° C.) for a set duration of time to a suitable activating agent. A preferred activating agent is for example CdC12, which is applied as a layer, for instance by a wet-chemical process or via CVD or PVD methods, onto the CdTe layer.

Methods from prior art further provide that subsequently wet-chemical etching is performed on the cadmium telluride layer. To this end, the CdTe solar cell is exposed to an etching agent, for example it is dipped into a so-called NP etching solution. Said NP etching solution is an aqueous solution of various inorganic acids, preferably (HNO3:H3PO4:H2O). This is done in the temperature range of room temperature (18° C. to about 80° C.). Etching time is preferably in the range of 5 sec to 60 sec. Resulting from the etching process a Te-rich layer is formed, the thickness of which ranges from 1 nm to 300 nm.

Subsequently in methods from prior art often a Sb2Te3 layer is applied, preferably by sputtering on the Sb2Te3. Afterwards, further layers of the back contact layer sequence are applied, typically consisting of molybdenum and nickel. A corresponding method is, for example, described in U.S. Pat. No. 7,211,462 B1; however in said publication there is no etching step, and merely a CdC12 treatment of the CdS/CdTe layer stack takes place. The Sb2Te3 layer is here applied by sputtering. In other known methods for applying the Sb2Te3 layer vaporizing or electrolytic deposition are intended. If required, several Sb2Te3 layers may also be intended.

In the substrate method, the above described order of producing the solar cell is inverted. On a substrate, first the back contact layer is created, whereby the substrate itself may also serve as back contact. Then the CdTe layer is applied, and a step for activating the CdTe layer is performed by means of an activation agent. Subsequently, on the activated CdTe layer a window layer, preferably made from pure or modified CdS (cadmium sulphide), and a transparent front contact layer (e.g. TCO—transparent conducting oxide) are deposited.

After application, the CdTe layer forms a polycrystalline layer. The size distribution of the CdTe crystals depends on the manner of process control, in particular on the temperature at which the CdTe grows on the CdS layer.

Studies have shown that the polycrystalline CdTe layer has a great number of crystal defects which disadvantageously decrease the lifetime and concentration of charge carriers.

### SUMMARY

Therefore the object is to reduce the number and extent of crystal defects in the CdTe layer.

According to the invention, the object is achieved with the method according to claim 1. Advantageous embodiments of the method are disclosed in the corresponding dependent subclaims.

In the following description of the method, the process steps of cleaning and sealing according to the state of the art are presumed to be known, and not explained in more detail. The deposition of anti-reflective and protective layers (such as back laminate or glass) is also presumed to be known.

Surprisingly it has been shown that the number and extension of crystal defects in the CdTe layer deposited on a substrate, which negatively impact the lifetime and concentration of charge carriers, may be reduced significantly by means of a further temperature step. Depending on the production method used, the constitution of the substrate may vary. In the superstrate method the substrate consists of a transparent substrate, the front contact layer deposited thereon, and a window layer, whereby the CdTe layer is applied on the window layer. In the substrate method, the substrate comprises a back contact layer, on which the CdTe layer is applied. The terms “front contact layer” and “back contact layer” here not only describe an individual layer, but also describe a potential layer sequence consisting of several layers applied one over the other.

Essential in this context is the requirement that this temperature step takes place after activating the CdTe layer and the subsequent step to remove the residual activation agent from the CdTe layer. Preferably, the temperature step is performed directly after these steps.

When performing the temperature step, the substrate is introduced in a heating chamber for a duration of preferably 5 minutes to 60 minutes, more preferably 10 minutes to 45 minutes, and particularly preferably 15 minutes to 30 minutes. In the heating chamber, the temperature is preferably set to 180° C. to 380° C., more preferably from 200° C. to 350° C., and particularly preferably from 220° C. to 320° C. The heating chamber may contain a standard atmosphere, an inert gas atmosphere, or alternatively a vacuum. Whereas the pressure in a standard or inert gas atmosphere is 1 bar, in the vacuum it is preferably reduced to between 10-3 and 10-4 mbar.

Removal of the activation agent preferably takes place using one of two alternative process methods:

a) the layer of the activation agent is either removed without previous cooling of the substrate containing the already applied layer sequence, after layer activation, or b) the activation agent layer is removed after cooling the substrate.

In process method a) an evaporation step at over 400° C. under vacuum or alternatively sputter etching are used. Advantageously in this method cooling and subsequent heating of the substrate is avoided. A disadvantage is that the additional temperature treatment could initiate diffusion processes having negative effects on the final results.

In process method b) rinsing of the CdTe surface after cooling is intended, using a suitable solvent. The preferred solvent used is deionized water, however, using other solvents, such as alcohols, weak acids, lyes, or mixtures of different solvents, is also possible. An advantage is that this is a tried and tested process step from prior art; a disadvantage is the necessity of re-heating the substrate.

In variant a) the substrate, with the applied CdTe layer, is introduced into the heating chamber preferably directly after removing (e.g. evaporating) the residual activation agent, respectively the temperature in the heating chamber is decreased to that required for the additional temperature step. Since the substrate has already been heated in the previous process step, the substrate temperature is correspondingly reduced to that prevailing in the heating chamber. After temperature adjustment, a constant temperature is maintained.

In variant b) the substrate with the CdTe layer is introduced into the pre-heated heating chamber after removing (rinsing off) the residual activation agent. Here, too, the temperature is kept constant after the substrate has reached the temperature prevailing in the heating chamber.

If the heating chamber is executed as a vacuum chamber or filled with inert gas, the substrate is introduced into the heating chamber optionally by means of a lock according to the state of the art.

If the thin-film solar cell is produced using the superstrate method, the additional temperature step may take place before or after applying the back contact layer. The additional temperature step according to the invention is preferably performed directly after removing the residual activation agent.

If the additional temperature step takes place before applying the back contact layer, and provided the method for producing thin-film solar cells comprises an etching step as described according to the state of the art for treating the CdTe surface, then the additional temperature step is performed before said etching step. Thereby it is avoided that the modification of the CdTe surface intended by means of the etching process is affected negatively by the temperature treatment. Furthermore, in this case preferably a lower temperature is chosen for the additional temperature step, so that a lower substrate temperature, preferably less than 350° C., prevails. This avoids a partial evaporation of the CdTe layer.

In an alternative process method it is intended that the additional temperature step is performed after applying the back contact layer. In this case an etching step for treating the CdTe surface may take place before the temperature step, because at that stage the CdTe surface is covered with the back contact layer, and therefore a degradation of the CdTe surface due to the effect of the temperature does not happen. Furthermore, in this case a higher temperature (preferably higher than 200° C.), may be selected for the additional temperature step, which favourably affects the diffusion processes required for healing the defects in the CdTe layer.

If the thin-film solar cell is produced using the substrate method, the additional temperature step preferably takes place prior to applying the window layer, e.g. one made of CdS. During the temperature step a lower temperature is selected, so that a substrate temperature of less than 350° C. is attained to avoid a partial evaporation of the CdTe layer.

In another preferred embodiment for the substrate method, the additional temperature step is performed after applying the window layer and prior to applying the front contact layer, or after applying both the window layer and the front contact layer. To perform the additional temperature step after applying the window layer is particularly advantageous in the case of performing—in addition to the activation step after applying the CdTe layer—a further activation step after applying the window layer. In this case, the method according to the invention comprises the following steps:
Making available a substrate,
Applying a back contact layer onto the substrate,
Applying a CdTe layer onto the back contact layer,
Activating the CdTe layer with a suitable activation agent,
Removing the residual activation agent from the CdTe layer after activation,
Applying a window layer onto the CdTe layer,
Activating the window layer with a suitable activation agent,
Removing the residual activation agent from the window layer after activation,
Applying a front contact layer on the window layer, and

Performing a temperature treatment under vacuum or in a heating chamber filled with air or inert gas, during which treatment the substrate is exposed to a temperature ranging from 180° C. to 380° C. for a duration of 5 minutes to 60 minutes.

The step for temperature treatment is thereby performed after removing the activation agent from the window layer, that is, before or after applying the front contact layer. If the additional temperature step is performed after applying the front contact layer, a higher temperature, preferably over 200° C., may be selected for the additional temperature step, which has a favourable effect on the diffusion processes required for healing the defects in the CdTe layer.

By means of the additional temperature step according to the invention, the electric efficiency of the solar cell is further improved. The highest measured increase in electric efficiency was 0.9 percentage points.

### BRIEF DESCRIPTION OF THE DRAWINGS

FIG. 1 shows the heating ramp for heating a substrate under vacuum.

FIG. 2 shows the heating ramp for heating a substrate in an oven in a standard atmosphere.

### DETAILED DESCRIPTION

The substrates used in the following exemplary embodiments serve, for the major part, for research purposes. The substrates are made from float glass, having dimensions of 10 cm×10 cm and a thickness of 3.2 mm. Onto these substrates, in the exemplary embodiments 1 and 2, the TCO layers, the CdS layers and the CdTe layers have already been deposited. If substrates are used on an industrial scale, these dimensions may significantly exceed an edge length (i.e. feed size) of 1 metre. For these substrates, the heating ramp requires adjustment to reduce the danger of breaking caused by thermal stress. The corresponding permissible heating rates are known from prior art. The most essential factor for the method according to the invention is however, that the substrate is kept for the time indicated at the temperatures indicated.

### 1. Vacuum Heating Chamber

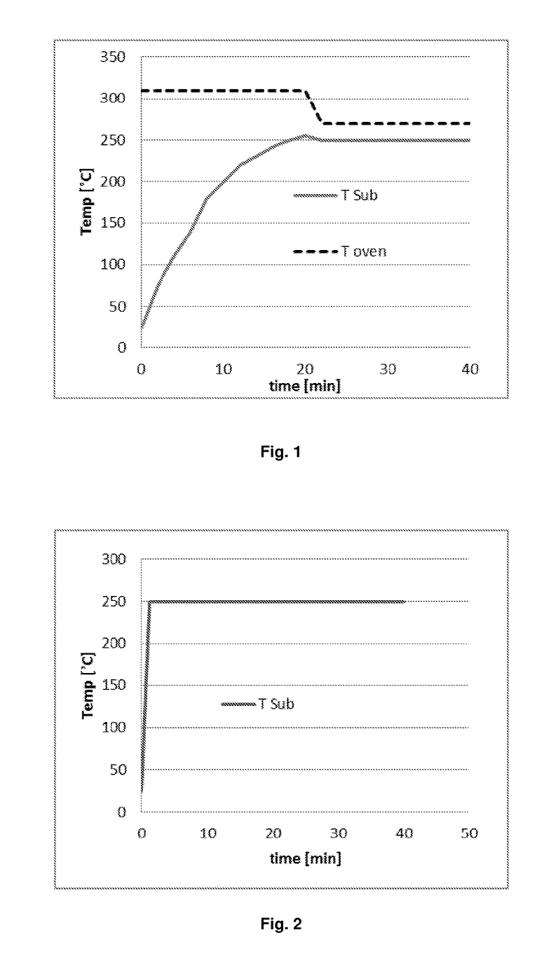

The heating ramp is shown in FIG. 1.

A substrate according to the state of the art is introduced into a vacuum heating chamber. For heating, a resistance heating according to the state of the art is used. The initial temperature of the substrate is at room temperature (20° C.). The end temperature of the substrate is 250° C. The oven temperature during feed-in of samples is 310° C. The substrate is heated up at a rate of about 11.5° C./minute over a time of about 20 minutes. The substrate reaches its end temperature of 250° C. Subsequently the oven temperature is reduced to 270° C. and the substrate is heated for 20 minutes at the same temperature. After the temperature step, the substrate is discharged from the heating chamber and left to cool under ambient conditions.

2. Heating Chamber with Air

Die heating ramp is shown in FIG. 2.

The substrate having ambient temperature (20° C.) is introduced into the heating chamber, which has been heated up to 250° C. and has a standard atmospheric pressure, and left there for a duration of 40 minutes. The temperature rise in the substrate is about 300° C./minutes.

### 3. Method for Producing a Solar Cell Using a Temperature Step According to the Invention

Cadmium sulfide and cadmium telluride are applied using CSS deposition onto a glass substrate coated with TCO. The layer thickness is c. 70 nm for the CdS and 4 μm for the CdTe. Deposition takes place at about 500° C. Subsequently, a CdC12-containing aqueous solution is applied, followed by a layer activation at 400° C. for a duration of 25 minutes exposed to air. Afterwards, the substrate is cooled down, the excess CdC12 is rinsed off using water, and the substrate is dried exposed to air.

Method 3a: The substrate (containing the layer sequence already present) is fed into a pre-heated vacuum chamber and the sample is annealed at 250° C. for a total duration of 40 minutes (the temperature profile corresponds to that shown in FIG. 1). Subsequently the substrate is discharged and cooled down (6-9° C./minutes) to room temperature, being exposed to air.

Method 3b: The substrate (containing the layer sequence already present) is fed into an atmospheric oven pre-heated to 250° C. (placing the substrate onto a hot graphite sheet) and subsequently annealed for 20 minutes. Thereafter cooling of the substrate to room temperature (6-9° C./minutes) takes place, exposed to air.

Only after this step (in method 3a or 3b), nitric-phosphoric acid etching takes place at ambient temperature (20° C.) for a duration of 30 seconds (NP-etching: HNO3:H3PO4:H2O). As a result of the etching a Te-rich layer of about 150 nm thickness is formed.

Finally, the substrate is fed into a vacuum chamber and the metallic back contact is deposited.

1. A method for producing a thin-film solar cell, comprising the steps:
a. Applying a CdTe layer onto a substrate,
b. Activating the CdTe layer using a suitable activation agent,
c. Removing the residual activation agent from the CdTe layer after activation, and
d. Performing a temperature treatment under vacuum or in a heating chamber filled with either air, or inert gas, after removing the residual activation agent, during which treatment the substrate is exposed to a temperature between 180° C. and 380° C. for a time between 5 minutes and 60 minutes.

2. The method according to claim 1, wherein in step c) the residual activation agent is evaporated off, and afterwards the additional temperature treatment takes place without any interim cooling.

3. The method according to claim 1, wherein, after activation of the CdTe layer, the substrate containing the layer sequence already present is cooled down to room temperature, and the residual activation agent is rinsed off with a suitable solvent in step c), after which the additional temperature treatment takes place.

4. The method according to claim 3, wherein the solvent is either deionized water, an alcohol, a weak acid, a lye, or a mixture of various substances.

5. The method according to claim 1, wherein the activation agent is CdC12.

6. The method according to claim 1, further comprising the steps:
e. Providing a transparent substrate,
f. Applying a front contact layer onto the substrate,
g. Applying a window layer onto the front contact layer,
h. Applying a back contact layer,
wherein the steps a) to d) are performed after step g), and step d) is performed either before or after step h).

7. The method according to claim 6, wherein step d) is performed before step h), wherein the resulting temperature of the substrate during step d) is less than 350° C.

8. The method according to claim 7, wherein the method further comprises an etching step for the surface treatment of the CdTe layer, wherein said etching step takes place after step d).

9. The method according to claim 6, wherein step d) takes place after step h), wherein during step d) the substrate is exposed to a temperature of more than 200° C.

10. The method according to claim 1, further comprising the steps:
i. Providing a substrate,
j. Applying a back contact layer onto the substrate,
k. Applying a window layer,
l. Applying a front contact layer onto the window layer,
wherein the steps a) to c) are performed between step j) and step k), and step d) is performed after step c) and before step k), or between the steps k) and l), or after step l).

11. The method according to claim 10, wherein step d) is performed before step k), wherein the resulting temperature of the substrate during step d) is less than 350° C.

12. The method according to claim 10, wherein step d) is performed after step l), wherein during step d) the substrate is exposed to a temperature of more than 200° C.

13. The method according to claim 6, wherein the window layer consists of pure or modified CdS.

14. The method according to claim 2, wherein the activation agent is CdC12.

15. The method according to claim 3, wherein the activation agent is CdC12.

16. The method according to claim 4, wherein the activation agent is CdC12.

17. The method according to claim 2, further comprising the steps:
e. Providing a transparent substrate,
f. Applying a front contact layer onto the substrate,
g. Applying a window layer onto the front contact layer,
h. Applying a back contact layer,
wherein the steps a) to d) are performed after step g), and step d) is performed either before or after step h).

18. The method according to claim 3, further comprising the steps:
e. Providing a transparent substrate,
f. Applying a front contact layer onto the substrate,
g. Applying a window layer onto the front contact layer,
h. Applying a back contact layer,
wherein the steps a) to d) are performed after step g), and step d) is performed either before or after step h).

19. The method according to claim 4, further comprising the steps:
e. Providing a transparent substrate,
f. Applying a front contact layer onto the substrate,
g. Applying a window layer onto the front contact layer,
h. Applying a back contact layer,
wherein the steps a) to d) are performed after step g), and step d) is performed either before or after step h).

20. The method according to claim 5, further comprising the steps:
e. Providing a transparent substrate,
f. Applying a front contact layer onto the substrate,
g. Applying a window layer onto the front contact layer,
h. Applying a back contact layer,
wherein the steps a) to d) are performed after step g), and step d) is performed either before or after step h).
